(19) United States
(12) Patent Application Publication
(10) Pub. No.: US 2025/0377259 A1
(43) Pub. Date: Dec. 11, 2025

(54) LIQUID LEAKAGE DETECTION CIRCUIT, SYSTEM AND METHOD, ELECTRONIC DEVICE AND STORAGE MEDIUM

(71) Applicant: SUZHOU METABRAIN INTELLIGENT TECHNOLOGY CO., LTD., Suzhou, Jiangsu (CN)

(72) Inventor: Bin YANG, Suzhou, Jiangsu (CN)

(73) Assignee: SUZHOU METABRAIN INTELLIGENT TECHNOLOGY CO., LTD., Suzhou, Jiangsu (CN)

(21) Appl. No.: 18/879,007

(22) PCT Filed: Dec. 13, 2023
(86) PCT No.: PCT/CN2023/138568

§ 371 Date: Dec. 26, 2024

(30) Foreign Application Priority Data
Feb. 22, 2023 (CN) 202310147661.6

(51) Int. Cl. G01M 3/40; G01M 3/00; H05K 7/20

(52) U.S. Cl. CPC G01M 3/40; G01M 3/007; H05K 7/20254; H05K 7/20763

(57) ABSTRACT

A liquid leakage detection circuit, comprising a sensing line anomaly detection trigger sub-circuit and a liquid leakage detection sub-circuit; are connected by a liquid leakage sensing line, wherein the sensing line anomaly detection trigger sub-circuit is configured to be conducted according to a liquid leakage simulation signal generated by a complex programmable logic device, so as to perform anomaly detection on the liquid leakage sensing line by the liquid leakage detection sub-circuit; and the liquid leakage detection sub-circuit is configured to perform anomaly detection on the liquid leakage sensing line according to a change condition of an input voltage when it is determined that the sensing line anomaly detection trigger sub-circuit is conducted, and to perform liquid leakage detection after it is determined that the liquid leakage sensing line has no anomaly condition.

### CROSS-REFERENCE TO RELATED APPLICATIONS

The present application is a National Stage Application of PCT International Application No.: PCT/CN2023/138568 filed on Dec. 13, 2023, which claims priority to Chinese Patent Application 202310147661.6, filed in the China National Intellectual Property Administration on Feb. 22, 2023, the disclosure of which is incorporated herein by reference in its entirety.

### TECHNICAL FIELD

The present disclosure relates to the technical field of heat dissipation of liquid-cooled servers, and in particular, to a liquid leakage detection circuit, system and method, an electronic device, and a non-transitory readable storage medium.

### BACKGROUND

With increasing requirements for server performance, powers of key components of a server, such as a Central Processing Unit (CPU), a Graphics Processing Unit (GPU), a Network Interface Controller (NIC), a Dual Inline Memory Module (DIMM), and a Solid State Drive (SSD) are also increasingly larger, and it is difficult for the air-cooling heat dissipation technology to solve heat dissipation problems of high-power CPUs and GPUs, etc.

Liquid-cooling heat dissipation has advantages of good heat dissipation effect, energy saving, environmental protection and low noise, and gradually becomes the mainstream heat dissipation mode for servers. A heat dissipation system of a liquid-cooled server includes internal circulation and external circulation of the server, wherein the internal circulation means that a liquid (cooling liquid) is delivered to a liquid-cooling pipe and a liquid-cooled cold plate from a Coolant Distribution Unit (CDU), takes heat away from heating devices, and then flows into the CDU to exchange heat with external cooling water, to finally bring the heat to an external water-cooling tower through the external circulation. Lines of the internal circulation are inside the liquid-cooled server, and there is necessarily a risk of liquid leakage which causes damage to a board card; therefore, usually a liquid leakage sensing line is wound on the liquid-cooling pipe and the liquid-cooled cold plate, and two ends of the liquid leakage sensing line are connected to a liquid leakage detection circuit on a main board of the liquid-cooled server to form a loop, so as to achieve liquid leakage detection.

In the current liquid-cooling heat dissipation liquid leakage detection apparatus, smooth detection can be achieved only when it is ensured that the liquid leakage sensing line is intact or plugged in position; however, currently, when liquid-cooled servers are produced, transported or repaired, conditions such as damage or fall-off of the liquid leakage sensing line are checked manually, and there is a problem of low manual detection accuracy. When liquid leakage occurs in the liquid-cooled server, the liquid leakage sensing line that is damaged or has a fall-off interface cannot detect the liquid leakage condition, causing short circuit and even damage of the liquid-cooled server due to the liquid leakage.

### SUMMARY

In view of the problems existing in the related art, some embodiments of the present disclosure provide a liquid leakage detection circuit, system and method, an electronic device, and a non-transitory readable storage medium.

Some embodiments of the present disclosure provide a liquid leakage detection circuit, including a sensing line anomaly detection trigger sub-circuit and a liquid leakage detection sub-circuit; the sensing line anomaly detection trigger sub-circuit and the liquid leakage detection sub-circuit are connected by a liquid leakage sensing line, wherein
the sensing line anomaly detection trigger sub-circuit is configured to be conducted according to a liquid leakage simulation signal generated by a complex programmable logic device, so as to perform anomaly detection on the liquid leakage sensing line by the liquid leakage detection sub-circuit, wherein the liquid leakage simulation signal is used to form a liquid leakage simulation scenario in the liquid leakage detection circuit when the sensing line anomaly detection trigger sub-circuit is conducted; and
the liquid leakage detection sub-circuit is configured to perform anomaly detection on the liquid leakage sensing line according to a change condition of an input voltage when it is determined that the sensing line anomaly detection trigger sub-circuit is conducted, and to perform liquid leakage detection after it is determined that the liquid leakage sensing line has no anomaly condition.

According to the liquid leakage detection circuit provided in some embodiments of the present disclosure, the liquid leakage sensing line is composed of a first wire and a second wire, and the liquid leakage sensing line is wound around a target area corresponding to a liquid-cooling pipe.

According to the liquid leakage detection circuit provided in some embodiments of the present disclosure, the liquid leakage detection sub-circuit includes a first resistor, a second resistor, and a comparator circuit, wherein
a first end of the first wire is connected to a first end of the first resistor, a first end of the second resistor and a first input end of the comparator circuit, and a second end of the first wire is connected to the sensing line anomaly detection trigger sub-circuit;
a second end of the first resistor is connected to a power-supplying source, and a second end of the second resistor is grounded; and
a second input end of the comparator circuit is connected to a reference power source, and an output end of the comparator circuit is connected to an input end of the complex programmable logic device, and is configured to generate a corresponding level signal according to a comparison result of a first input voltage and a second input voltage, such that the complex programmable logic device determines a liquid leakage condition of the target area according to the level signal, wherein the first input voltage is an input voltage inputted to the first input end of the comparator circuit, and the second input voltage is an input voltage inputted to the second input end of the comparator circuit.

According to the liquid leakage detection circuit provided in some embodiments of the present disclosure, the comparator circuit is configured to generate a high-level signal when it is determined that the input voltage of the first input end of the comparator circuit is greater than the input voltage of the second input end of the comparator circuit, such that the complex programmable logic device determines that the target area has no liquid leakage condition according to the high-level signal; and generate a low-level signal when it is determined that the input voltage of the first input end of the comparator circuit is less than the input voltage of the second input end of the comparator circuit, such that the complex programmable logic device determines that the target area has a liquid leakage condition according to the low-level signal.

According to the liquid leakage detection circuit provided in some embodiments of the present disclosure, the sensing line anomaly detection trigger sub-circuit is composed of a switching circuit and is configured to be conducted when the liquid leakage simulation signal is received, such that when the sensing line anomaly detection trigger sub-circuit is conducted, if the liquid leakage detection sub-circuit generates the low-level signal, the complex programmable logic device determines that the liquid leakage sensing line has no anomaly condition according to the low-level signal; and if the liquid leakage detection sub-circuit generates the high-level signal, the complex programmable logic device determines that the liquid leakage sensing line has an anomaly condition according to the high-level signal;
wherein a first input end of the switching circuit is connected to an output end of the complex programmable logic device, a second input end of the switching circuit is connected to a second end of the second wire, an output end of the switching circuit is connected to the second end of the first wire, and a first end of the second wire is grounded.

According to the liquid leakage detection circuit provided in some embodiments of the present disclosure, the sensing line anomaly detection trigger sub-circuit is further configured to be disconnected after receiving a simulation shutdown signal generated by the complex programmable logic device.

Some embodiments of the present disclosure further provide a liquid leakage detection system, including a liquid leakage sensing line, a liquid leakage detection controller, and the liquid leakage detection circuit by means of any one above, wherein
the liquid leakage sensing line and the liquid leakage detection circuit are connected to each other, and are deployed in a target area corresponding to a liquid-cooling pipe to be detected in a liquid-cooled server;
the liquid leakage detection controller is connected to the liquid leakage detection circuit, and is configured to acquire a sensing line anomaly detection result or a liquid leakage detection result sent by the liquid leakage detection circuit, and generate a corresponding alarm signal according to the sensing line anomaly detection result or the liquid leakage detection result; and
the liquid leakage detection circuit is configured to detect an anomaly condition or liquid leakage condition of the liquid leakage sensing line.

According to the liquid leakage detection system provided in some embodiments of the present disclosure, the liquid leakage detection controller includes a complex programmable logic device and a baseboard manager controller, wherein
the complex programmable logic device is connected to the liquid leakage detection circuit, and is configured to send a liquid leakage simulation signal to the liquid leakage detection circuit according to a sensing line anomaly detection signal sent by the baseboard manager controller, so as to start the liquid leakage detection circuit to perform anomaly detection on the liquid leakage sensing line to acquire the sensing line anomaly detection result; and configured to, after the baseboard manager controller determines that the liquid leakage sensing line has no anomaly condition, start the liquid leakage detection circuit to perform liquid leakage detection according to the liquid leakage detection signal sent by the baseboard manager controller, to acquire the liquid leakage detection result of the target area; and
the baseboard manager controller is connected to the complex programmable logic device via an inter integrated circuit, and is configured to generate a corresponding alarm signal according to the sensing line anomaly detection result or the liquid leakage detection result.

According to the liquid leakage detection system provided in some embodiments of the present disclosure, Optionally, the complex programmable logic device is further configured to after the baseboard manager controller determines that the liquid leakage sensing line has no anomaly condition, generate a simulation shutdown signal according to a sensing line anomaly detection shutdown signal sent by the baseboard manager controller, and send the simulation shutdown signal to the liquid leakage detection circuit, so as to shut down the anomaly detection performed by the liquid leakage detection circuit on the liquid leakage sensing line.

According to the liquid leakage detection system provided in some embodiments of the present disclosure, the baseboard manager controller is connected to a power supply unit via a power management bus, and the power supply unit is configured to turn off a power source of the liquid-cooled server according to the alarm signal generated by the baseboard manager controller.

According to the liquid leakage detection system provided in some embodiments of the present disclosure, the complex programmable logic device is connected to the power supply unit via a general-purpose input/output, and the complex programmable logic device is connected to the baseboard manager controller via the general-purpose input/output for heartbeat signal detection, and if it is determined that the baseboard manager controller has an anomaly condition according to the heartbeat signal detection result, a power off signal is generated and sent to the power supply unit, wherein the power supply unit is configured to turn off a power source of the liquid-cooled server according to the power off signal generated by the complex programmable logic device.

According to the liquid leakage detection system provided in some embodiments of the present disclosure, the complex programmable logic device is further configured to judge whether a heartbeat signal is received within a preset period, and determine an anomaly condition of the baseboard manager controller according to the judgment result.

According to the liquid leakage detection system provided in some embodiments of the present disclosure, the liquid leakage detection system includes a plurality of the liquid leakage detection circuits, and each liquid leakage detection circuit is correspondingly provided according to a deployment area where the liquid leakage sensing line is provided in the liquid-cooled server.

According to the liquid leakage detection system provided in some embodiments of the present disclosure, the liquid leakage detection system further includes an alarm display module, wherein the alarm display module is connected to the baseboard manager controller via a network, and is configured to display corresponding liquid leakage sensing line alarm content according to the sensing line anomaly detection result or the liquid leakage detection result sent by the baseboard manager controller.

According to the liquid leakage detection system provided in some embodiments of the present disclosure, the alarm display module is further configured to display liquid leakage sensing line alarm content corresponding to different liquid leakage alarm levels according to liquid leakage area position information corresponding to the liquid leakage detection result.

Some embodiments of the present disclosure further provide a liquid leakage detection method based on the liquid leakage detection system according to any one above, including:
by means of a liquid leakage detection circuit, sensing line anomaly detection is performed on a liquid leakage sensing line of a liquid-cooling pipe in a liquid-cooled server, and liquid leakage detection is performed on a target area corresponding to the liquid-cooling pipe after it is determined that the liquid leakage sensing line has no anomaly condition; and
by means of a liquid leakage detection controller, a corresponding alarm signal is generated according to a sensing line anomaly detection result or a liquid leakage detection result sent by the liquid leakage detection circuit.

According to the liquid leakage detection method provided in some embodiments of the present disclosure, a corresponding alarm signal is generated according to the sensing line anomaly detection result or the liquid leakage detection result sent by the liquid leakage detection circuit, includes:
a corresponding alarm risk level is acquired according to the sensing line anomaly detection result or the liquid leakage detection result; and
a corresponding alarm signal is generated by the alarm risk level.

According to the liquid leakage detection method provided in some embodiments of the present disclosure, a method of acquiring a corresponding alarm risk level according to the sensing line anomaly detection result, includes:
anomaly area position information corresponding to a target liquid leakage sensing line having an anomaly condition in the liquid-cooled server is acquired according to the sensing line anomaly detection result; and
a corresponding sensing line alarm risk level is generated according to the anomaly area position information.

According to the liquid leakage detection method provided in some embodiments of the present disclosure, a corresponding alarm risk level is acquired according to the liquid leakage detection result, includes:
liquid leakage area position information corresponding to a liquid-cooling pipe having a liquid leakage condition in the liquid-cooled server is acquired according to the liquid leakage detection result; and
a corresponding liquid leakage alarm risk level is generated according to the liquid leakage area position information.

Some embodiments of the present disclosure further provide an electronic device, including a memory, a processor, and a computer program stored on the memory and executable on the processor, wherein the processor, when executing the program, implements the liquid leakage detection method according to any one above.

Some embodiments of the present disclosure further provide a non-transitory computer non-transitory readable storage medium, on which a computer program is stored, and the computer program, when executed by a processor, implements the liquid leakage detection method according to any one above.

According to the liquid leakage detection circuit, system and method, the electronic device and the non-transitory readable storage medium provided in some embodiments of the present disclosure, by generating the liquid leakage simulation signal, anomaly conditions such as damage or fall-off of the liquid leakage sensing line of the liquid-cooling pipe in the liquid-cooled server are detected, such that anomaly conditions of the liquid leakage sensing line are automatically detected more accurately; and when it is determined that the liquid leakage sensing line has no anomaly condition, liquid leakage detection is performed on the liquid-cooling pipe, thereby improving the stability of liquid leakage detection of the liquid-cooled server.

### BRIEF DESCRIPTION OF THE DRAWINGS

In order to describe the technical solutions in some embodiments of the present disclosure or in the related art more clearly, hereinafter, accompanying drawings requiring to be used in the embodiments or the related art will be introduced briefly. Apparently, the accompanying drawings in the following description merely relate to some embodiments of the present disclosure, and for a person of ordinary skill in the art, other accompanying drawings can also be obtained according to these accompanying drawings without involving any inventive effort.

FIG. 1 is a schematic structural diagram of a liquid leakage detection circuit provided according to some embodiments of the present disclosure;

FIG. 2 is a schematic diagram of an overall structure of the liquid leakage detection circuit provided according to some embodiments of the present disclosure;

FIG. 3 is a schematic structural diagram of a liquid leakage detection system provided according to some embodiments of the present disclosure;

FIG. 4 is a schematic diagram of an overall structure of a liquid leakage detection system of a liquid-cooled server provided according to some embodiments of the present disclosure;

FIG. 5 is a schematic flowchart of a liquid leakage detection method provided according to some embodiments of the present disclosure;

FIG. 6 is a schematic diagram of an overall flow of a liquid leakage detection method for a liquid-cooled server provided according to some embodiments of the present disclosure; and

FIG. 7 is a schematic structural diagram of an electronic device provided according to some embodiments of the present disclosure.

### DETAILED DESCRIPTION OF THE EMBODIMENTS

To make the objects, technical solutions and advantages of some embodiments of the present disclosure clearer, hereinafter, the technical solutions in some embodiments of the present disclosure will be described clearly and thoroughly in combination with the accompanying drawings in some embodiments of the present disclosure. Obviously, the embodiments as described are only some rather than all the embodiments of the present disclosure. All other embodiments obtained by a person of ordinary skill in the art on the basis of the embodiments of the present disclosure without involving any inventive effort shall all fall within the scope of protection of the present disclosure.

In the existing liquid-cooling liquid leakage detection technology, a liquid leakage sensing line is spirally wound on a cooling pipe (i.e. a liquid-cooling pipe, the pipe being used for conveying a cooling liquid) of a liquid-cooled server, wherein the outer layer of the liquid leakage sensing line is a water-absorption coating layer, and the liquid leakage sensing line is internally provided with a metal wire. The liquid leakage sensing line is electrically connected to a liquid leakage detection circuit, the liquid leakage detection circuit is electrically connected to a liquid leakage detection controller, and the liquid leakage detection controller is electrically connected to an alarm device, a display screen and a server power-supplying source, respectively. When liquid leakage occurs, the liquid is infiltrated into the liquid leakage sensing line, the resistance value of the liquid leakage sensing line becomes smaller and smaller after being infiltrated, such that the liquid leakage sensing line is conducted, and the liquid leakage detection circuit detects a liquid leakage sensing line conduction signal and transmits same to the liquid leakage detection controller, such that the alarm device is controlled by the liquid leakage detection controller to give an alarm, and a power-supplying source of the server is turned off.

Smooth detection can be achieved only when the liquid leakage sensing line is intact or plugged in position; however, currently, when liquid-cooled servers are produced, transported or repaired, anomaly conditions such as damage or fall-off of the liquid leakage sensing line (such as an interface between the liquid leakage sensing line and the liquid leakage detection circuit is not successfully plugged) are all checked manually, and even if labor cost is increased, there is still a condition in which the inspection is inadequate. When the liquid leakage sensing line has the anomaly conditions above, if liquid leakage occurring in the liquid-cooling pipe in the liquid-cooled server cannot be detected, the liquid-cooled server will be short-circuited or even damaged due to the liquid leakage.

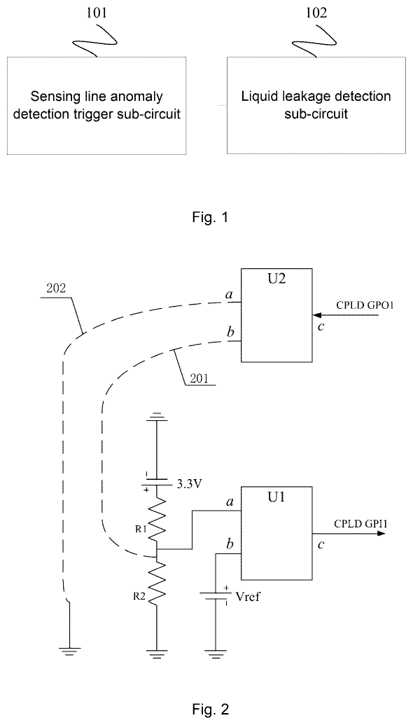

FIG. 1 is a schematic structural diagram of a liquid leakage detection circuit provided according to some embodiments of the present disclosure. As shown in FIG. 1, some embodiments of the present disclosure provide a liquid leakage detection circuit, including a sensing line anomaly detection trigger sub-circuit 101 and a liquid leakage detection sub-circuit 102; the sensing line anomaly detection trigger sub-circuit 101 and the liquid leakage detection sub-circuit 102 are connected via a liquid leakage sensing line, wherein
the sensing line anomaly detection trigger sub-circuit 101 is configured to be conducted according to a liquid leakage simulation signal generated by a complex programmable logic device, so as to perform anomaly detection on the liquid leakage sensing line by the liquid leakage detection sub-circuit, wherein the liquid leakage simulation signal is used to form a liquid leakage simulation scenario in the liquid leakage detection circuit when the sensing line anomaly detection trigger sub-circuit is conducted; and
the liquid leakage detection sub-circuit 102 is configured to perform anomaly detection on the liquid leakage sensing line according to a change condition of an input voltage when it is determined that the sensing line anomaly detection trigger sub-circuit 101 is conducted, and to perform liquid leakage detection after it is determined that the liquid leakage sensing line has no anomaly condition.

In some embodiments of the present disclosure, the sensing line anomaly detection trigger sub-circuit 101 is electrically connected to the complex programmable logic device (CPLD), and by adjusting a level signal outputted by the CPLD, the sensing line anomaly detection trigger sub-circuit 101 is conducted. In some embodiments of the present disclosure, when the CPLD outputs a high level (i.e. the liquid leakage simulation signal), the sensing line anomaly detection trigger sub-circuit 101 is conducted, and at this time, the liquid leakage detection circuit will manufacture a liquid leakage simulation scenario, so as to perform liquid leakage detection in the liquid leakage simulation scenario via the liquid leakage detection sub-circuit 102.

In some embodiments of the present disclosure, the liquid leakage simulation signal generated by the CPLD may be generated in an initialization manner after the initial installation of the liquid-cooled server is completed, that is, after it is confirmed that the liquid leakage sensing line is installed, each interface condition of the liquid leakage sensing line is detected by means of a trigger signal of a baseboard manager controller (BMC), and whether each interface is correctly installed is judged. Therefore, in some embodiments of the present disclosure, by simulating one liquid leakage signal, the liquid leakage detection sub-circuit 102 in the liquid leakage detection circuit performs anomaly detection on the installation condition of the liquid leakage sensing line. If the liquid leakage sensing line is not correctly installed (for example, a port of the liquid leakage detection circuit is not correctly plugged into an interface of the liquid leakage sensing line, and a fall-off condition exists), in the liquid leakage simulation scenario, the liquid leakage detection sub-circuit 102 should generate a corresponding level signal (such as a low-level signal) according to a change condition of an input voltage to judge the existence of the liquid leakage condition (the liquid leakage condition in the simulation scenario); however, if a detection result corresponding to an actually produced level signal (a high-level signal) indicates a no liquid leakage condition, at this time, it can be judged that the liquid leakage sensing line has fall-off or damage conditions; and if the liquid leakage detection sub-circuit 102 generates a correct level signal in the liquid leakage simulation scenario, it can be determined that the liquid leakage sensing line does not have fall-off or damage conditions at this time. In some optional embodiments, after maintenance personnel maintain the liquid-cooling pipe and the corresponding liquid leakage sensing line in the liquid-cooled server, the BMC may also send a trigger signal to the CPLD, such that the CPLD generates one piece of liquid leakage simulation information for anomaly detection, and detects conditions such as fall-off or damage of the liquid leakage sensing line caused by the maintenance.

Optionally, after it is determined that the liquid leakage sensing line has no anomaly condition, liquid leakage detection is performed on the liquid-cooling pipe in real time by the liquid leakage detection sub-circuit 102. In some embodiments of the present disclosure, the liquid leakage sensing line is deployed below the liquid-cooling pipe, and when liquid leakage occurs in the pipe, the cooling liquid is infiltrated into the liquid leakage sensing line, such that the liquid leakage sensing line is connected and conducted, and at this time, the liquid leakage detection sub-circuit 102 generates a corresponding level signal, so as to obtain a liquid leakage detection result.

According to the liquid leakage detection circuit provided by some embodiments of the present disclosure, by generating the liquid leakage simulation signal, anomaly conditions such as damage or fall-off of the liquid leakage sensing line of the liquid-cooling pipe in the liquid-cooled server are detected, such that anomaly conditions of the liquid leakage sensing line are automatically detected more accurately; and when it is determined that the liquid leakage sensing line has no anomaly condition, liquid leakage detection is performed on the liquid-cooling pipe, thereby improving the stability of liquid leakage detection of the liquid-cooled server.

Optionally, the liquid leakage sensing line is composed of a first wire and a second wire, and the liquid leakage sensing line is wound around a target area corresponding to the liquid-cooling pipe;
wherein the anomaly conditions at least include an interface fall-off condition and a damage condition of the liquid leakage sensing line.

In some embodiments of the present disclosure, the liquid leakage sensing line includes a left side 2-pin connector (including a left-side first pin and a left-side second pin), a right-side 2 pin-connector (including a right-side first pin and a right-side second pin) and a sensing line; the sensing line includes an outer braided layer, an inner braided layer, a first wire (a plurality of strands of wire cores) and a second wire (a plurality of strands of wire cores); wherein the outer braided layer and the inner braided layer have a water absorption function, and when liquid leakage occurs in the liquid-cooling pipe, the cooling liquid can be effectively absorbed and infiltrated into the first wire and the second wire. In normal situations, that is, when there is no liquid leakage, the first wire and the second wire are in a disconnected state, and after liquid leakage occurs, the cooling liquid is absorbed and infiltrated into the sensing line, and due to the conductive effect of the liquid, the first wire and the second wire are in a conducted state. It should be noted that, in some embodiments of the present disclosure, the left-side 2-pin connector and the right-side 2-pin connector correspond to two ports of the first wire and the second wire, for example, the left-side first pin is a first port of the first wire, the left-side second pin is a first port of the second wire, the right-side first pin is a second port of the first wire, and the right-side second pin is a second port of the second wire; or, the left-side first pin is a first port of the second wire, the left-side second pin is a first port of the first wire, the right-side first pin is a second port of the second wire, and the right-side second pin is a second port of the first wire, which are not specifically limited in some embodiments of the present disclosure.

Optionally, the liquid leakage sensing line is deployed in a reasonable winding manner, and as interface positions and welding point positions on a cold plate are risk points of leakage of the cooling liquid, the liquid leakage sensing line needs to be wound to various interface positions and welding point positions; moreover, at the liquid-cooling pipe, the liquid leakage sensing line selects to be laid straight along the pipe, and the liquid leakage sensing line is located below the liquid-cooling pipe and is wound and fixed by an adhesive tape, to detect the liquid leakage condition at any position on the liquid-cooling cold plate and the liquid-cooling pipe, so as to ensure the normal operation of the liquid-cooled server.

In some embodiments of the present disclosure, when it is determined that the liquid leakage sensing line is not damaged and the interface area has no fall-off, if no liquid leakage occurs in the liquid-cooling pipe, at this time, the liquid leakage sensing line is disconnected, the liquid leakage detection sub-circuit 102 outputs a first level signal (a high-level signal), and the CPLD detection result is that liquid-cooling heat dissipation has no liquid leakage condition; and if liquid leakage occurs in the liquid-cooling pipe, the liquid leakage sensing line is conducted, and at this time, the liquid leakage detection sub-circuit 102 outputs a second level signal (a low-level signal), and the CPLD detection result is that the liquid-cooling heat dissipation has a liquid leakage condition.

Optionally, the liquid leakage detection sub-circuit includes a first resistor, a second resistor, and a comparator circuit, wherein
a first end of the first wire is connected to a first end of the first resistor, a first end of the second resistor and a first input end of the comparator circuit, and a second end of the first wire is connected to the sensing line anomaly detection trigger sub-circuit;
a second end of the first resistor is connected to a power-supplying source, and a second end of the second resistor is grounded; and
a second input end of the comparator circuit is connected to a reference power source, and an output end of the comparator circuit is connected to an input end of the complex programmable logic device, and is configured to generate a corresponding level signal according to a comparison result of a first input voltage and a second input voltage, such that the complex programmable logic device determines a liquid leakage condition of the target area according to the level signal, wherein the first input voltage is an input voltage inputted to the first input end of the comparator circuit, and the second input voltage is an input voltage inputted to the second input end of the comparator circuit.

FIG. 2 is a schematic diagram of an overall structure of the liquid leakage detection circuit provided according to some embodiments of some embodiments of the present disclosure. As shown in FIG. 2, in some embodiments of the present disclosure, the liquid leakage detection sub-circuit includes a first resistor R1, a second resistor R2, and a comparator circuit U1; the liquid leakage sensing line includes a first wire 201 and a second wire 202, wherein the left-side first pin (i.e. a first end of the second wire 202) of the liquid leakage sensing line is grounded, the left-side second pin (i.e. a first end of the first wire 201) of the liquid leakage sensing line is connected to the first resistor R1, the second resistor R2 and an input end a of the comparator circuit U1, the other end of the first resistor R1 is connected to a power-supplying source (providing a power supply voltage VCC (Volt Current Condenser)), and the other end of the second resistor R2 is grounded; and a reference power source (providing a reference voltage Vref (Voltage reference)) is connected to an input end b of the comparator circuit U1, and an output end c of the comparator circuit U1 is connected to an input port (GPI 1 (General-purpose input 1)) of a CPLD.

In some optional embodiments, numerical values of the first resistor R1, the second resistor R2, and the reference voltage may be adjusted, thereby improving the liquid leakage detection sensitivity of the comparator circuit U1.

Optionally, the sensing line anomaly detection trigger sub-circuit is composed of a switching circuit and is configured to be conducted when the liquid leakage simulation signal is received, such that when the sensing line anomaly detection trigger sub-circuit is conducted, if the liquid leakage detection sub-circuit generates the low-level signal, the complex programmable logic device determines that the liquid leakage sensing line has no anomaly condition according to the low-level signal; and if the liquid leakage detection sub-circuit generates the high-level signal, the complex programmable logic device determines that the liquid leakage sensing line has an anomaly condition according to the high-level signal;
wherein a first input end of the switching circuit is connected to an output end of the complex programmable logic device, a second input end of the switching circuit is connected to a second end of the second wire, an output end of the switching circuit is connected to the second end of the first wire, and the first end of the second wire is grounded.

Optionally, in some embodiments of the present disclosure, the right-side first pin of the liquid leakage sensing line (i.e. the second end of the second wire 202) is connected to an input end a of the switching circuit U2, the right-side second pin (i.e. the second end of the first wire 201) is connected to an output end b of the switching circuit U2, and an input end c of the switching circuit U2 is connected to an output end (GPO 1 (General-purpose output 1)) of the CPLD. In some embodiments of the present disclosure, signal transmission is achieved by a General-purpose input/output (GPIO) of the CPLD, and the switching circuit U2 is controlled to be conducted or disconnected by adjusting high and low-level signals outputted by the output end GPO 1 of the CPLD, so as to simulate a liquid leakage scenario to identify anomaly conditions such as damage or fall-off of the liquid leakage sensing line. In some optional embodiments, a plurality of groups of liquid leakage detection circuits may be provided to separately monitor key components in the liquid-cooled server, such as a CPU cold plate, a water cooling pipe, a GPU cold plate and a water cooling pipe. It should be noted that, in some embodiments of the present disclosure, the switching circuit U2 is used as a switching circuit, has two states of “conduction” and “disconnection”, and conduction and disconnection of the circuit can be achieved according to an output signal of the CPLD.

Optionally, the comparator circuit is configured to generate a high-level signal when it is determined that the input voltage of the first input end of the comparator circuit is greater than the input voltage of the second input end of the comparator circuit, such that the complex programmable logic device determines that the target area has no liquid leakage condition according to the high-level signal; and generate a low-level signal when it is determined that the input voltage of the first input end of the comparator circuit is less than the input voltage of the second input end of the comparator circuit, such that the complex programmable logic device determines that the target area has a liquid leakage condition according to the low-level signal.

In some embodiments of the present disclosure, as shown in FIG. 2, the power supply voltage VCC is set as 3.3 V, and the reference power source Vref is set as 2.24 V; in a normal no liquid leakage state, the first wire 201 and the second wire 202 in the liquid leakage sensing line are not connected, and at this time, the liquid leakage sensing line is in a disconnected state, and the resistance value thereof is equivalent to infinity, and the input voltage of the input end a of the comparator circuit U1 is determined according to the resistance values of the first resistor R1 and the second resistor R2 and the power supply voltage VCC; wherein the power supply voltage VCC is selected according to actual requirements, for example, 3.3 V or 5 V. In some embodiments of the present disclosure, by setting the resistance values of the first resistor R1 and the second resistor R2 in the liquid leakage detection circuit, when the liquid leakage sensing line is disconnected, the input voltage of the input end a of the comparator circuit U1 is close to the power supply voltage VCC, e.g. 3.3 V, which is higher than the input voltage 2.24 V at the input end b of the comparator circuit U1; at this time, the output end c of the comparator circuit U1 outputs a high level, which is identified as a no liquid leakage state by the CPLD. When liquid leakage occurs, the liquid leakage sensing line is conducted, the resistance value thereof is relatively small, and the input end a of the comparator circuit U1 is equivalent to adding a parallel resistor to the second resistor R2; at this time, the input voltage of the input end a of the comparator circuit U1 will be reduced, for example, the input voltage of the input end a of the comparator circuit U1 is 0.7 V (the value can be adjusted according to the actual circuit structure), which is lower than the input voltage 2.24 V of the input end b of the comparator circuit U1; in this case, the output end c of the comparator circuit U1 outputs a low level, which is identified as liquid leakage by the CPLD. In some embodiments of the present disclosure, the output level of the output end c of the comparator circuit U1 changes under normal and liquid leakage conditions, corresponding high and low-level signals are generated, and then sent to the CPLD for identification, and finally a corresponding liquid leakage condition alarm is generated.

In some embodiments of the present disclosure, when anomaly detection is performed on the liquid leakage sensing line, a liquid leakage detection function of the liquid leakage detection sub-circuit is also used, and it is only that in this scenario, the liquid leakage scenario is formed by simulation of the sensing line anomaly detection trigger sub-circuit. Therefore, in the liquid leakage simulation scenario, if liquid leakage is detected by the liquid leakage detection sub-circuit, the CPLD judges that the liquid leakage sensing line is correctly plugged or not damaged according to the received low-level signal; and when the liquid leakage detection sub-circuit has not detected liquid leakage, it indicates that the liquid leakage sensing line has an anomaly condition, such that the generated high-level signal is sent to the CPLD for identification, and finally a corresponding anomaly prompt is generated, to inform the maintenance personnel of inspection and repair, thereby improving the stability and safety of liquid leakage detection, which prevents situations that liquid leakage cannot be accurately detected in subsequent liquid-cooling heat dissipation caused by conditions such as damage or fall-off of the liquid leakage sensing line during production, transportation or repair of liquid-cooled servers.

Optionally, the sensing line anomaly detection trigger sub-circuit is further configured to be disconnected after receiving a simulation shutdown signal generated by the complex programmable logic device.

In some embodiments of the present disclosure, anomaly detection of the liquid leakage sensing line can be performed after initial installation or inspection and repair of the liquid-cooled server according to actual anomaly detection requirements of the liquid leakage sensing line; and after the anomaly detection is completed, a low-level signal can be generated by the CPLD, such that the sensing line anomaly detection trigger sub-circuit is disconnected, which will not affect a subsequent real-time liquid leakage detection process.

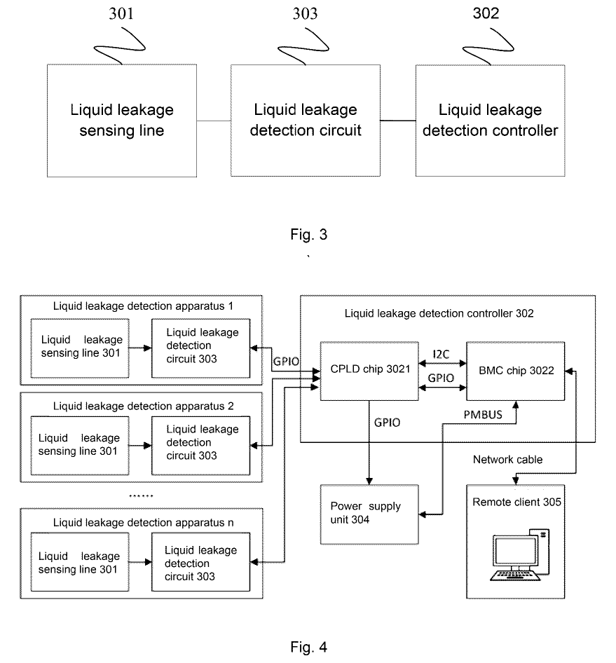

FIG. 3 is a schematic structural diagram of a liquid leakage detection system provided according to some embodiments of the present disclosure. As shown in FIG. 3, some embodiments of the present disclosure provide a liquid leakage detection system, including a liquid leakage sensing line 301, a liquid leakage detection controller 302, and a liquid leakage detection circuit 303, wherein
the liquid leakage sensing line 301 and the liquid leakage detection circuit 303 are connected to each other, and are deployed in a target area corresponding to a liquid-cooling pipe to be detected in a liquid-cooled server;
the liquid leakage detection controller 302 is connected to the liquid leakage detection circuit 303, and is configured to acquire a sensing line anomaly detection result or a liquid leakage detection result sent by the liquid leakage detection circuit 303, and generate a corresponding alarm signal according to the sensing line anomaly detection result or the liquid leakage detection result; and
the liquid leakage detection circuit 303 is configured to detect an anomaly condition or liquid leakage condition of the liquid leakage sensing line 301.

In some embodiments of the present disclosure, braided layers in the liquid leakage sensing line 301 have a water absorption function, and when liquid leakage occurs in the liquid-cooling pipe, the cooling liquid can be effectively absorbed and infiltrated into the sensing line. In a normal no liquid leakage state, the liquid leakage sensing line 301 is in a disconnected state; and when liquid leakage occurs, the cooling liquid is absorbed and infiltrated into the sensing line, and due to the conductive effect of the cooling liquid, the liquid leakage sensing line 301 is in a conducted state.

In some optional embodiments, the liquid leakage detection controller 302 may use devices of the liquid-cooled server itself, and optionally, the liquid leakage detection controller includes a complex programmable logic device and a baseboard manager controller, wherein
the complex programmable logic device is connected to the liquid leakage detection circuit, and is configured to send a liquid leakage simulation signal to the liquid leakage detection circuit according to a sensing line anomaly detection signal sent by the baseboard manager controller, so as to start the liquid leakage detection circuit to perform anomaly detection on the liquid leakage sensing line to acquire the sensing line anomaly detection result; and configured to, after the baseboard manager controller determines that the liquid leakage sensing line has no anomaly condition, start the liquid leakage detection circuit to perform liquid leakage detection according to the liquid leakage detection signal sent by the baseboard manager controller, to acquire the liquid leakage detection result of the target area; and
the baseboard manager controller is connected to the complex programmable logic device via an inter integrated circuit, and is configured to generate a corresponding alarm signal according to the sensing line anomaly detection result or the liquid leakage detection result.

FIG. 4 is a schematic diagram of an overall structure of a liquid leakage detection system of a liquid-cooled server provided according to some embodiments of the present disclosure. As shown in FIG. 4, in this embodiment, a liquid leakage sensing line 301 and a liquid leakage detection circuit 303 constitute a liquid leakage detection apparatus, and a liquid leakage detection controller 302 includes a CPLD chip 3021 and a baseboard manager controller (BMC) chip 3022; an output end of the liquid leakage detection circuit 303 is electrically connected to an input end GPI 1 of the CPLD chip 3021, an input end of the liquid leakage detection circuit 303 is electrically connected to an output end GPO 1 of the CPLD chip 3021, and the CPLD chip 3021 communicates with the BMC chip 3022 via an Inter Integrated Circuit (I2C), such that the CPLD chip 3021 sends a corresponding control signal to the liquid leakage detection circuit 303 according to a trigger signal (such as a sensing line anomaly detection signal or a liquid leakage detection signal) sent by the BMC chip 3022, so as to realize liquid leakage detection or sensing line anomaly detection.

Optionally, the baseboard manager controller is connected to a power supply unit via a power management bus, and the power supply unit is configured to turn off a power source of a liquid-cooled server according to an alarm signal generated by the baseboard manager controller.

In some embodiments of the present disclosure, with reference to FIG. 4, electrical connection to the power supply unit 304 (PSU) of the liquid-cooled server is achieved via an GPIO interface of the CPLD chip 3021. An output end of the BMC chip 3022 is electrically connected to the power supply unit 304 via a power management bus (PMBUS), and is in network connection with a remote client 305 in a wireless or wired manner.

Optionally, when liquid leakage occurs in a liquid-cooling pipe in the liquid-cooled server, a level signal outputted by the liquid leakage detection circuit 303 changes, and at this time, via the GPI 1, the liquid leakage detection circuit 303 notifies the CPLD chip 3021 of liquid leakage of key components such as a CPU cold plate and a water cooling pipe or a GPU cold plate and a water cooling pipe of the liquid-cooled server. Optionally, the CPLD chip 3021 notifies the BMC chip 3022 of specific liquid leakage position via the I2C bus (for example, according to deployment area information corresponding to the liquid leakage sensing line 301), the BMC chip 3022 gives an alarm to the remote client 305 via network connection, and the power supply unit 304 of the liquid-cooled server is powered off via the PMBUS.

According to the liquid leakage detection system provided in some embodiments of the present disclosure, by generating the liquid leakage simulation signal, anomaly conditions such as damage or fall-off of the liquid leakage sensing line of the liquid-cooling pipe in the liquid-cooled server are detected, such that anomaly conditions of the liquid leakage sensing line are automatically detected more accurately; and when it is determined that the liquid leakage sensing line has no anomaly conditions, liquid leakage detection is performed on the liquid-cooling pipe, thereby improving the stability of liquid leakage detection of the liquid-cooled server.

Optionally, the complex programmable logic device is further configured to after the baseboard manager controller determines that the liquid leakage sensing line has no anomaly condition, generate a simulation shutdown signal according to a sensing line anomaly detection shutdown signal sent by the baseboard manager controller, and send the simulation shutdown signal to the liquid leakage detection circuit, so as to shut down the anomaly detection performed by the liquid leakage detection circuit on the liquid leakage sensing line.

In some embodiments of the present disclosure, by adjusting a level signal (such as a high- level signal and a low-level signal) outputted by the GPO 1 of the CPLD, a sensing line anomaly detection trigger sub-circuit in the liquid leakage detection circuit 303 is conducted and disconnected, such that the liquid leakage detection circuit simulates one liquid leakage scenario, thereby detecting whether anomaly conditions such as damage or fall-off exist in the liquid leakage sensing line. Optionally, in some embodiments of the present disclosure, according to a preset sensing line detection condition, for example, after initial installation of the liquid-cooled server is completed or after maintenance personnel inspects and repairs the liquid-cooling pipe of the liquid-cooled server, the BMC generates a trigger signal, such that the CPLD generates a conduction signal (i.e. the liquid leakage simulation signal); and after sensing line anomaly detection is completed, the BMC sends a sensing line anomaly detection shutdown signal to the CPLD, such that the CPLD generates a shutdown signal (i.e. simulation shutdown information), thereby completing the current leakage sensing line anomaly detection, so as to improve the stability of subsequent liquid leakage detection.

Optionally, the complex programmable logic device is connected to the power supply unit via a general-purpose input/output, and the complex programmable logic device is connected to the baseboard manager controller via the general-purpose input/output for heartbeat signal detection, and if it is determined that the baseboard manager controller has an anomaly condition according to the heartbeat signal detection result, a power off signal is generated and sent to the power supply unit, wherein the power supply unit is configured to turn off a power source of the liquid-cooled server according to the power off signal generated by the complex programmable logic device.

When the existing liquid leakage detection controller performs liquid leakage protection, the key depends on normal operation of the BMC chip, especially the I2C module, and when liquid leakage occurs in the liquid-cooled server and the BMC chip is in anomaly conditions such as failure, upgrade and restart, the liquid leakage condition cannot be detected or the power-supplying source of the liquid-cooled server cannot be powered off, such that the liquid-cooled server is short-circuited or even damaged due to the liquid leakage. For the situations above, in some embodiments of the present disclosure, the CPLD chip collects the heartbeat signal of the BMC chip, and when heartbeat signal of the BMC chip is not received, it is judged that the BMC chip has a failure, such that a power source turning-off operation is performed on the liquid-cooled server via the CPLD chip under the anomaly conditions such as BMC failure, upgrade and restart, thereby improving the safety.

Optionally, the complex programmable logic device is further configured to judge whether a heartbeat signal is received within a preset period, and determine an anomaly condition of the baseboard manager controller according to the judgment result.

In some embodiments of the present disclosure, the preset period may be set, for example, if the CPLD chip has not received a heartbeat signal sent by the BMC chip within 10 s, it is judged that the BMC chip is anomalous, and at this time, the CPLD chip pulls a Power-ok signal low via the GPIO, thereby forcibly turning off the PSU of the liquid-cooled server, which improves the reliability and safety of the liquid-cooled server.

Optionally, the liquid leakage detection system includes a plurality of the liquid leakage detection circuits, and each liquid leakage detection circuit is correspondingly provided according to a deployment area where the liquid leakage sensing line is provided in the liquid-cooled server.

In some embodiments of the present disclosure, refer to FIG. 4, according to the number of liquid-cooling pipes in the liquid-cooled server, corresponding number of liquid leakage sensing lines 301 are provided, and each liquid leakage sensing line 301 is connected to a liquid leakage detection circuit 303 corresponding thereto. That is, in some embodiments of the present disclosure, according to information of areas to be subjected to liquid leakage detection in the liquid-cooled server, corresponding number of liquid leakage detection apparatuses are provided, such that liquid leakage detection is performed on each liquid-cooling pipe in the liquid-cooled server, and also rapid positioning for a liquid leakage generation area is achieved.

Optionally, the liquid leakage detection system further includes an alarm display module, wherein the alarm display module is connected to the baseboard manager controller via a network, and is configured to display corresponding liquid leakage sensing line alarm content according to the sensing line anomaly detection result or the liquid leakage detection result sent by the baseboard manager controller.

In some embodiments of the present disclosure, refer to FIG. 4, the BMC chip 3022 provides an alarm option or an alarm-and-power-off option, such that the alarm display module (which may be implemented by the remote client 305) may configure, via a WEB (World Wide Web) interface or a command line interface, the liquid-cooled server to have only an alarm option or an alarm-and-power-off option after liquid leakage occurs in the liquid-cooled server, such that remote operation and maintenance personnel execute a corresponding policy according to the liquid leakage severity of the liquid leakage detection device.

Optionally, the alarm display module is further configured to display liquid leakage sensing line alarm content corresponding to different liquid leakage alarm levels according to liquid leakage area position information corresponding to the liquid leakage detection result.

With regard to the existing problem that after liquid leakage occurs in a liquid-cooled server, a liquid leakage detection controller automatically turns off a power-supplying source of the server, which easily causes service loss, in some embodiments of the present disclosure, the alarm display module generates a corresponding liquid leakage alarm level by liquid leakage conditions occurring in different areas according to the acquired liquid leakage detection result, so as to provide a more intuitive display interface for maintenance personnel, such that the operation and maintenance personnel execute a corresponding policy according to alarm priority, thereby increasing the liquid leakage fault processing efficiency.

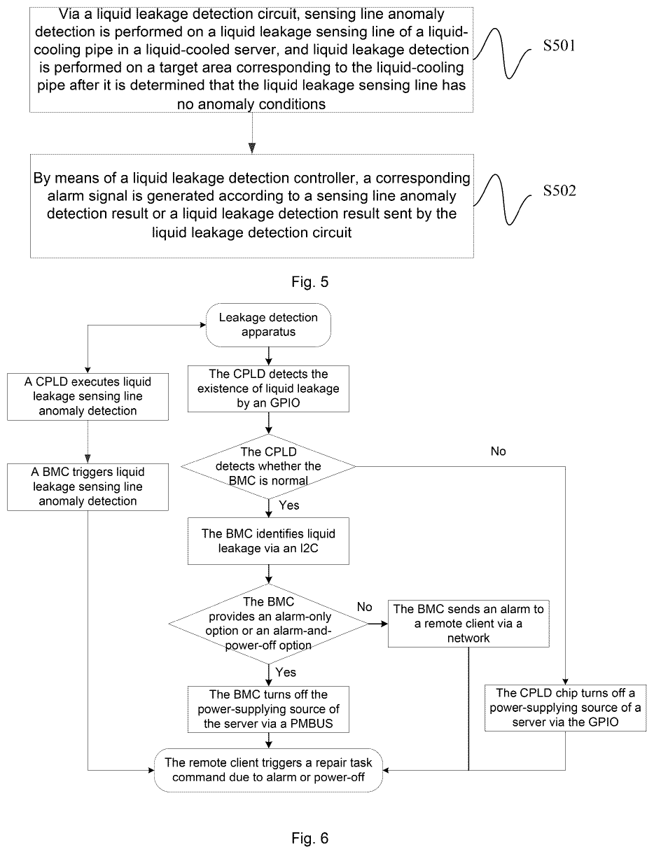

FIG. 5 is a schematic flowchart of a liquid leakage detection method provided according to some embodiments of the present disclosure. As shown in FIG. 5, some embodiments of the present disclosure provide a liquid leakage detection method of a liquid leakage detection system, including:

step 501: via a liquid leakage detection circuit, sensing line anomaly detection is performed on a liquid leakage sensing line of a liquid-cooling pipe in a liquid-cooled server, and liquid leakage detection is performed on a target area corresponding to the liquid-cooling pipe after it is determined that the liquid leakage sensing line has no anomaly conditions.

In some embodiments of the present disclosure, a liquid leakage simulation signal is sent to the liquid leakage detection circuit via CPLD chip, so as to start the liquid leakage detection circuit to perform anomaly detection on the liquid leakage sensing line, and after it is determined that the liquid leakage sensing line has no anomaly condition, liquid leakage detection is further performed on the target area corresponding to the liquid leakage sensing line.

Step 502: by means of a liquid leakage detection controller, a corresponding alarm signal is generated according to a sensing line anomaly detection result or a liquid leakage detection result sent by the liquid leakage detection circuit.

In some embodiments of the present disclosure, by using a water absorption function of braided layers in the liquid leakage sensing line, when liquid leakage occurs in the liquid-cooling pipe, the cooling liquid can be effectively absorbed and infiltrated into the sensing line. In a normal liquid leakage-free state, the liquid leakage sensing line is in a disconnected state; and when liquid leakage occurs, the cooling liquid is absorbed and infiltrated into the sensing line, and due to the conductive effect of the cooling liquid, the liquid leakage sensing line is in a conducted state. In some embodiments of the present disclosure, when liquid-cooling heat dissipation is normal, the liquid leakage sensing line is disconnected, and a first level signal is outputted to the liquid leakage detection controller, and the identification result is no liquid leakage; and when liquid leakage occurs in the liquid-cooling heat dissipation, the liquid leakage sensing line is conducted, and a second level signal is outputted to the liquid leakage detection controller, and liquid leakage is identified.

The liquid-cooling pipe is in a normal liquid leakage-free state, the liquid leakage sensing line is in a disconnected state, and the resistance value thereof is equivalent to infinity, and at this time, the liquid leakage detection circuit outputs a high level, which is identified as a liquid leakage-free state by the CPLD chip. When liquid leakage occurs, the liquid leakage sensing line is conducted, and the resistance value thereof is relatively small, and in this case, the liquid leakage detection circuit outputs a low level, which is identified as liquid leakage by the CPLD chip. Moreover, in the anomaly detection process of the liquid leakage sensing line, it is a simulation liquid leakage scenario, if the liquid leakage detection circuit detects liquid leakage, it is judged that the liquid leakage sensing line is correctly plugged or not damaged; while when the liquid leakage detection circuit does not detect liquid leakage, it indicates that the liquid leakage sensing line has an anomaly condition, such that maintenance personnel can be prompted to make inspection and repair, thereby improving the stability and safety of liquid leakage detection.

According to the liquid leakage detection method provided in some embodiments of the present disclosure, by generating the liquid leakage simulation signal, anomaly conditions such as damage or fall-off of the liquid leakage sensing line of the liquid-cooling pipe in the liquid-cooled server are detected, such that anomaly conditions of the liquid leakage sensing line are automatically detected more accurately; and when it is determined that the liquid leakage sensing line has no anomaly conditions, liquid leakage detection is performed on the liquid-cooling pipe, thereby improving the stability of liquid leakage detection of the liquid-cooled server.

Optionally, a corresponding alarm signal is generated according to the sensing line anomaly detection result or the liquid leakage detection result sent by the liquid leakage detection circuit, includes:
a corresponding alarm risk level is acquired according to the sensing line anomaly detection result or the liquid leakage detection result; and
a corresponding alarm signal is generated by the alarm risk level.

In some embodiments of the present disclosure, when the liquid leakage detection circuit detects that there is an anomaly in the current liquid leakage condition or the liquid leakage sensing line, the liquid leakage detection result or the sensing line anomaly detection result may be sent to a remote client for alarm, and a PSU of the liquid-cooled server is turned off; in addition, a corresponding alarm risk level is generated according to the liquid leakage detection result or the sensing line anomaly detection result, so as to be provided to the maintenance personnel for executing a corresponding policy.

Optionally, a method of acquiring a corresponding alarm risk level according to the sensing line anomaly detection result, includes:
anomaly area position information corresponding to a target liquid leakage sensing line having an anomaly condition in the liquid-cooled server is acquired according to the sensing line anomaly detection result; and
a corresponding sensing line alarm risk level is generated according to the anomaly area position information.

Optionally, a corresponding alarm risk level is acquired according to the liquid leakage detection result, includes:
liquid leakage area position information corresponding to a liquid-cooling pipe having a liquid leakage condition in the liquid-cooled server is acquired according to the liquid leakage detection result; and
a corresponding liquid leakage alarm risk level is generated according to the liquid leakage area position information.

In some embodiments of the present disclosure, the risk level of the alarm signal is determined according to the liquid leakage detection result or the sensing line anomaly detection result generated in different detection areas, and thus according to the alarm risk level, corresponding options are provided for maintenance personnel to evaluate, for example, an alarm-only-without-power-off option is used for remote operation and maintenance personnel to evaluate the liquid leakage severity, and then perform subsequent processing, such as power-off and alarm node and node service migration; or detection results generated by CPU and GPU areas have a higher risk level, and maintenance personnel need to remove faults as soon as possible (also can implement automatic power-off processing).

FIG. 6 is a schematic diagram of an overall flow of a liquid leakage detection method for a liquid-cooled server provided according to some embodiments of the present disclosure. With reference to FIG. 6, after a liquid-cooled server completes initial installation, an anomaly detection process for a liquid leakage sensing line is triggered by a BMC, and then a liquid leakage simulation signal is generated by a CPLD chip, such that a liquid leakage detection apparatus executes anomaly detection of the liquid leakage sensing line; and when the liquid leakage detection apparatus is anomalous, for example, the liquid leakage sensing line is not in place, an open circuit or a short circuit, the CPLD chip detects anomaly of the liquid leakage sensing line and corresponding position information, and notifies the BMC chip, such that after receiving the anomaly of the liquid leakage sensing line and the position information thereof, the BMC chip notifies a remote client, and thus the remote client executes a corresponding policy according to alarm priority.

Optionally, when the liquid leakage detection apparatus is normal, that is, the liquid leakage sensing line is not damaged and plugged normally and does not fall off, liquid leakage detection is performed by means of a liquid leakage detection circuit in the liquid leakage detection apparatus, and then it is judged that the liquid-cooled server works normally at this time.

Optionally, when the liquid leakage detection apparatus detects a liquid leakage condition, the CPLD chip sends the detected liquid leakage condition and the position information thereof to the BMC chip, and after the BMC chip receives the liquid leakage condition and the position information thereof, an alarm-only option is generated according to the BMC, thereby sending the corresponding alarm information to the remote client; or an alarm and power-down option is generated according to the BMC, and the alarm is sent to the remote client and a power-supplying source of the server is turned off, such that maintenance personnel execute a corresponding policy according to the alarm priority displayed by the remote client.

While the liquid leakage detection apparatus performs liquid leakage detection, the CPLD chip judges whether the BMC chip is anomalous by a heartbeat signal of the BMC chip, and when it is detected that the BMC chip is alive (normal), it indicates that the liquid leakage detection process can be normally performed; and when the CPLD chip cannot detect a heartbeat signal of the BMC chip (after repeated detection attempts for a preset number of times), it is judged that the BMC chip is anomalous, and at this time, the CPLD chip turns off the power-supplying source of the server via a GPIO, for maintenance personnel to execute a corresponding policy according to the alarm priority via the remote client.

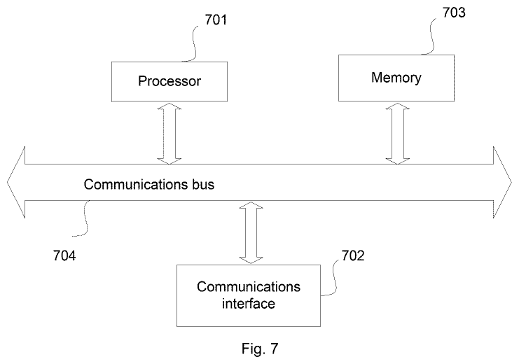

FIG. 7 is a schematic structural diagram of an electronic device provided according to some embodiments of the present disclosure. As shown in FIG. 7, the electronic device may include: a processor 701, a communications interface 702, a memory 703, and a communications bus 704, wherein the processor 701, the communications interface 702, and the memory 703 communicate with each other via the communications bus 704. The processor 701 may invoke logic instructions in the memory 703 to execute the liquid leakage detection method, and the method includes: by means of a liquid leakage detection circuit, sensing line anomaly detection is performed on a liquid leakage sensing line of a liquid-cooling pipe in a liquid-cooled server, and liquid leakage detection is performed on a target area corresponding to the liquid-cooling pipe after it is determined that the liquid leakage sensing line has no anomaly conditions; and a liquid leakage detection controller, a corresponding alarm signal is generated according to a sensing line anomaly detection result or a liquid leakage detection result sent by the liquid leakage detection circuit.

In addition, the logic instructions in the memory 703 may be implemented in the form of a software functional unit and sold or used as an independent product, and may be stored in a computer non-transitory readable storage medium. On the basis of such understanding, the part of the technical solutions of some embodiments of the present disclosure that contributes in essence or to the related art or part of the technical solutions may be embodied in the form of a software product; the computer software product is stored in a non-transitory readable storage medium and includes several instructions to enable a computer device (which may be a personal computer, a server or a network device, etc.) to execute all or some of the steps of the method described in various embodiments of the present disclosure. Moreover, the non-transitory readable storage medium above includes: media such as a USB flash disk, a mobile hard disk, a Read-Only Memory (ROM), a Random Access Memory (RAM), a magnetic disk, or an optical disk, and the like which can store program codes.

In another aspect, some embodiments of the present disclosure further provide In another aspect, some embodiments of the present disclosure further provide a computer program product, wherein the computer program product includes a computer program stored on a non-transitory computer non-transitory readable storage medium, the computer program includes program instructions, and when the program instructions are executed by a computer, the computer can execute the liquid leakage detection method provided by the method above, and the method includes: by means of a liquid leakage detection circuit, sensing line anomaly detection is performed on a liquid leakage sensing line of a liquid-cooling pipe in a liquid-cooled server, and liquid leakage detection is performed on a target area corresponding to the liquid-cooling pipe after it is determined that the liquid leakage sensing line has no anomaly conditions; and by means of a liquid leakage detection controller, a corresponding alarm signal is generated according to a sensing line anomaly detection result or a liquid leakage detection result sent by the liquid leakage detection circuit.

In still another aspect, some embodiments of the present disclosure further provide a non-transitory computer non-transitory readable storage medium, on which a computer program is stored, and the computer program, when executed by a processor, implements to execute the liquid leakage detection method according to the embodiments above, and the method includes: by means of a liquid leakage detection circuit, sensing line anomaly detection is performed on a liquid leakage sensing line of a liquid-cooling pipe in a liquid-cooled server, and liquid leakage detection is performed on a target area corresponding to the liquid-cooling pipe after it is determined that the liquid leakage sensing line has no anomaly conditions; and by means of a liquid leakage detection controller, a corresponding alarm signal is generated according to a sensing line anomaly detection result or a liquid leakage detection result sent by the liquid leakage detection circuit.

The apparatus embodiments as described above are merely exemplary, wherein units described as separate components may or may not be physically separated, and the components displayed as units may or may not be physical modules, that is, may be located in one place, or may be distributed in a plurality of network units. Some or all of the modules may be selected according to actual needs to achieve the purpose of the solutions of the embodiments. A person of ordinary skill in the art would understand and implement the embodiments without any inventive effort.

From the description of the described embodiments, a person skilled in the art would have been able to clearly understand that the embodiments may be implemented by using software and necessary general hardware platforms, and of course may also be implemented using hardware. On the basis of such understanding, the portion of the technical solutions that contributes in essence or contributes to the related art may be embodied in the form of a software product; the computer software product is stored in a computer non-transitory readable storage medium (such as an ROM/RAM, a magnetic disk and an optical disc), and includes several instructions to cause a computer device (which may be a personal computer, a server or a network device, etc.) to execute the method in various embodiments or the method in certain parts of the embodiments.

Finally, it should be noted that the embodiments above are only used to illustrate rather than limit the technical solutions of some embodiments the present disclosure. Although some embodiments of the present disclosure have been explained in detail with reference to the embodiments above, a person of ordinary skill in the art would have understood: they still could modify the technical solutions disclosed in the described embodiments or make equivalent replacements to some technical features therein. Moreover, these modifications or replacements shall not render that the nature of the corresponding technical solutions departs from the spirit and scope of the technical solutions in embodiments of the present disclosure.

1. A liquid leakage detection circuit, comprising a sensing line anomaly detection trigger sub-circuit and a liquid leakage detection sub-circuit; the sensing line anomaly detection trigger sub-circuit and the liquid leakage detection sub-circuit are connected via a liquid leakage sensing line, wherein
the sensing line anomaly detection trigger sub-circuit is configured to be conducted according to a liquid leakage simulation signal generated by a complex programmable logic device, so as to perform anomaly detection on the liquid leakage sensing line by the liquid leakage detection sub-circuit, wherein the liquid leakage simulation signal is used to form a liquid leakage simulation scenario in the liquid leakage detection circuit when the sensing line anomaly detection trigger sub-circuit is conducted; and
the liquid leakage detection sub-circuit is configured to perform anomaly detection on the liquid leakage sensing line according to a change condition of an input voltage when it is determined that the sensing line anomaly detection trigger sub-circuit is conducted, and to perform liquid leakage detection after it is determined that the liquid leakage sensing line has no anomaly condition.

2. The liquid leakage detection circuit according to claim 1, wherein the liquid leakage sensing line is composed of a first wire and a second wire, and the liquid leakage sensing line is wound around a target area corresponding to a liquid-cooling pipe.

3. The liquid leakage detection circuit according to claim 2, wherein the liquid leakage detection sub-circuit comprises a first resistor, a second resistor, and a comparator circuit, wherein
a first end of the first wire is connected to a first end of the first resistor, a first end of the second resistor and a first input end of the comparator circuit, and a second end of the first wire is connected to the sensing line anomaly detection trigger sub-circuit;
a second end of the first resistor is connected to a power-supplying source, and a second end of the second resistor is grounded; and
a second input end of the comparator circuit is connected to a reference power source, and an output end of the comparator circuit is connected to an input end of the complex programmable logic device, and is configured to generate a corresponding level signal according to a comparison result of a first input voltage and a second input voltage, such that the complex programmable logic device determines a liquid leakage condition of the target area according to the level signal, wherein the first input voltage is an input voltage inputted to the first input end of the comparator circuit, and the second input voltage is an input voltage inputted to the second input end of the comparator circuit.

4. The liquid leakage detection circuit according to claim 3, wherein the comparator circuit is configured to generate a high-level signal when it is determined that the input voltage of the first input end of the comparator circuit is greater than the input voltage of the second input end of the comparator circuit, such that the complex programmable logic device determines that the target area has no liquid leakage condition according to the high-level signal; and generate a low-level signal when it is determined that the input voltage of the first input end of the comparator circuit is less than the input voltage of the second input end of the comparator circuit, such that the complex programmable logic device determines that the target area has a liquid leakage condition according to the low-level signal.

5. The liquid leakage detection circuit according to claim 4, wherein the sensing line anomaly detection trigger sub-circuit is composed of a switching circuit and is configured to be conducted when the liquid leakage simulation signal is received, such that when the sensing line anomaly detection trigger sub-circuit is conducted, if the liquid leakage detection sub-circuit generates the low-level signal, the complex programmable logic device determines that the liquid leakage sensing line has no anomaly condition according to the low-level signal; and if the liquid leakage detection sub-circuit generates the high-level signal, the complex programmable logic device determines that the liquid leakage sensing line has an anomaly condition according to the high-level signal;
wherein a first input end of the switching circuit is connected to an output end of the complex programmable logic device, a second input end of the switching circuit is connected to a second end of the second wire, an output end of the switching circuit is connected to the second end of the first wire, and the first end of the second wire is grounded.

6. The liquid leakage detection circuit according to claim 1, wherein the sensing line anomaly detection trigger sub-circuit is further configured to be disconnected after receiving a simulation shutdown signal generated by the complex programmable logic device.

7. A liquid leakage detection system, comprising a liquid leakage sensing line, a liquid leakage detection controller, and the liquid leakage detection circuit according to claim 1, wherein
the liquid leakage sensing line and the liquid leakage detection circuit are connected to each other, and are deployed in a target area corresponding to a liquid-cooling pipe to be detected in a liquid-cooled server;
the liquid leakage detection controller is connected to the liquid leakage detection circuit, and is configured to acquire a sensing line anomaly detection result or a liquid leakage detection result sent by the liquid leakage detection circuit, and generate a corresponding alarm signal according to the sensing line anomaly detection result or the liquid leakage detection result; and
the liquid leakage detection circuit is configured to detect an anomaly condition or liquid leakage condition of the liquid leakage sensing line.

8. The liquid leakage detection system according to claim 7, wherein the liquid leakage detection controller comprises a complex programmable logic device and a baseboard manager controller, wherein
the complex programmable logic device is connected to the liquid leakage detection circuit, and is configured to send a liquid leakage simulation signal to the liquid leakage detection circuit according to a sensing line anomaly detection signal sent by the baseboard manager controller, so as to start the liquid leakage detection circuit to perform anomaly detection on the liquid leakage sensing line to acquire a sensing line anomaly detection result; and configured to, after the baseboard manager controller determines that the liquid leakage sensing line has no anomaly condition, start the liquid leakage detection circuit to perform liquid leakage detection according to the liquid leakage detection signal sent by the baseboard manager controller, to acquire the liquid leakage detection result of the target area; and
the baseboard manager controller is connected to the complex programmable logic device via an inter integrated circuit, and is configured to generate a corresponding alarm signal according to the sensing line anomaly detection result or the liquid leakage detection result.

9. The liquid leakage detection system according to claim 8, wherein the complex programmable logic device is further configured to after the baseboard manager controller determines that the liquid leakage sensing line has no anomaly condition, generate a simulation shutdown signal according to a sensing line anomaly detection shutdown signal sent by the baseboard manager controller, and send the simulation shutdown signal to the liquid leakage detection circuit, so as to shut down the anomaly detection performed by the liquid leakage detection circuit on the liquid leakage sensing line.

10. The liquid leakage detection system according to claim 8, wherein the baseboard manager controller is connected to a power supply unit via a power management bus, and the power supply unit is configured to turn off a power source of the liquid-cooled server according to the alarm signal generated by the baseboard manager controller.

11. The liquid leakage detection system according to claim 10, wherein the complex programmable logic device is connected to the power supply unit via a general-purpose input/output, and the complex programmable logic device is connected to the baseboard manager controller via the general-purpose input/output for heartbeat signal detection, and if it is determined that the baseboard manager controller has an anomaly condition according to the heartbeat signal detection result, a power off signal is generated and sent to the power supply unit, wherein the power supply unit is configured to turn off a power source of the liquid-cooled server according to the power off signal generated by the complex programmable logic device.

12. The liquid leakage detection system according to claim 11, wherein the complex programmable logic device is further configured to judge whether a heartbeat signal is received within a preset period, and determine an anomaly condition of the baseboard manager controller according to the judgment result.

13. The liquid leakage detection system according to claim 7, wherein the liquid leakage detection system comprises a plurality of the liquid leakage detection circuits, and each liquid leakage detection circuit is correspondingly provided according to a deployment area where the liquid leakage sensing line is provided in the liquid-cooled server.

14. The liquid leakage detection system according to claim 8, wherein the liquid leakage detection system further comprises an alarm display module, wherein the alarm display module is connected to the baseboard manager controller via a network, and is configured to display corresponding liquid leakage sensing line alarm content according to the sensing line anomaly detection result or the liquid leakage detection result sent by the baseboard manager controller.

15. The liquid leakage detection system according to claim 14, wherein the alarm display module is further configured to display liquid leakage sensing line alarm content corresponding to different liquid leakage alarm levels according to liquid leakage area position information corresponding to the liquid leakage detection result.

16. A liquid leakage detection method based on the liquid leakage detection system according to claim 7, comprising:
performing, by means of a liquid leakage detection circuit, sensing line anomaly detection on a liquid leakage sensing line of a liquid-cooling pipe in a liquid-cooled server, and performing liquid leakage detection on a target area corresponding to the liquid-cooling pipe after it is determined that the liquid leakage sensing line has no anomaly condition; and
generating, by means of a liquid leakage detection controller, a corresponding alarm signal according to a sensing line anomaly detection result or a liquid leakage detection result sent by the liquid leakage detection circuit.

17. The liquid leakage detection method according to claim 16, wherein generating a corresponding alarm signal according to the sensing line anomaly detection result or the liquid leakage detection result sent by the liquid leakage detection circuit, comprises:
acquiring a corresponding alarm risk level according to the sensing line anomaly detection result or the liquid leakage detection result; and
generating a corresponding alarm signal by the alarm risk level.

18. The liquid leakage detection method according to claim 17, wherein a method of acquiring a corresponding alarm risk level according to the sensing line anomaly detection result, comprises:
acquiring anomaly area position information corresponding to a target liquid leakage sensing line having an anomaly condition in the liquid-cooled server according to the sensing line anomaly detection result; and
generating a corresponding sensing line alarm risk level according to the anomaly area position information.

19. The liquid leakage detection method according to claim 17, wherein acquiring a corresponding alarm risk level according to the liquid leakage detection result, comprises:
acquiring liquid leakage area position information corresponding to a liquid-cooling pipe having a liquid leakage condition in the liquid-cooled server according to the liquid leakage detection result; and
generating a corresponding liquid leakage alarm risk level according to the liquid leakage area position information.

20. An electronic device, comprising a memory, a processor, and a computer program stored on the memory and executable on the processor, wherein the processor is configured to execute the computer program to implement the liquid leakage detection method as claimed in claim 16.

21. (canceled)
